(19) United States
(12) Patent Application Publication
(10) Pub. No.: US 2018/0033903 A1
(43) Pub. Date: Feb. 1, 2018

(54) STRUCTURE USING A THIN FILM TYPE SOLAR CELL

(71) Applicant: MOOHAN Co., Ltd., Gwangju-si, Gyeonggi-do (KR)

(72) Inventor: Heon Do KIM, Gwangju-si, Gyeonggi-do (KR)

(73) Assignee: MOOHAN Co., Ltd., Gwangju-si, Gyeonggi-do (KR)

(21) Appl. No.: 15/550,022

(22) PCT Filed: Mar. 12, 2015
(86) PCT No.: PCT/KR2015/002392

§ 371 Date: Aug. 9, 2017

(30) Foreign Application Priority Data
Feb. 27, 2015 (KR) 10-2015-0028341

(51) Int. Cl. H01L 31/075; H01L 31/0216; H01L 31/0224

(52) U.S. Cl. CPC H01L 31/075; H01L 31/022466; H01L 31/02167

(57) ABSTRACT

A structure using a thin film type solar cell is disclosed, which comprises an external plate exposed to solar rays; a first adhesive layer provided on an opposite surface of a surface of the external plate, which is exposed to the solar rays; a thin film type solar cell provided on the first adhesive layer; a second adhesive layer provided on the thin film type solar cell; and a protection layer provided on the second adhesive layer, wherein the second adhesive layer is made of a colored adhesive material.

### BACKGROUND OF THE INVENTION

### Field of the Invention

The present invention relates to a thin film type solar cell, and more particularly, to various types of structures using a thin film type solar cell applied to a window of a building or a sunroof of a car.

### Discussion of the Related Art

A solar cell converts a light energy into an electric energy by using a property of a semiconductor.

The solar cell has a PN junction structure where a positive (P)-type semiconductor makes a junction with a negative (N)-type semiconductor. When solar rays are incident upon the solar cell with the PN junction structure, holes (+) and electrons (−) are generated in the semiconductor by the incident energy of the solar rays. At this time, by an electric field generated due to the PN junction, the holes (+) are drifted toward the P-type semiconductor and the electrons (−) are drifted toward the N-type semiconductor, to generate electric potential, whereby an electric power may be produced with the occurrence of electric potential.

The solar cell may be categorized into a thin film type solar cell and a wafer type solar cell.

The thin film type solar cell is manufactured by forming a semiconductor on a substrate such as glass in a type of a thin film while the wafer type solar cell is manufactured using a silicon wafer as a substrate.

With respect to efficiency, although the wafer type solar cell is better than the thin film type solar cell, it has problems in that it is difficult to realize a small thickness due to difficulty in performance of the manufacturing process and its manufacturing cost is increased due to a high-priced semiconductor substrate. Particularly, since the wafer is opaque, there is a limitation in application of the wafer type solar cell to a structure, which may require lighting, such as a sunroof of a car or a window of a building.

Even though the thin film type solar cell is inferior in efficiency to the wafer type solar cell, it has advantages such as realization of a thin profile and use of a low-priced material, whereby the manufacturing cost of the thin film type solar cell may be reduced. Particularly, since a transparent glass substrate may be used, the thin film type solar cell is suitable for application to a structure, which may require lighting, such as a sunroof of a car or a window of a building.

Hereinafter, a thin film type solar cell according to the related art will be described with reference to the accompanying drawing.

FIG. 1 is a cross-sectional view illustrating a structure using a thin film type solar cell according to the related art.

As shown in FIG. 1, the structure using the thin film type solar cell according to the related art includes an external plate 1, an adhesive layer 2, and a thin film type solar cell 3.

The external plate 1 is provided on a surface, such as a window of a building or a sunroof of a car, which is exposed to solar rays. The external plate 1 may be made of a transparent material through which the solar rays may be transmitted, for example, glass or transparent plastic.

The adhesive layer 2 is formed on an inner surface of the external plate 1 to bond the thin film type solar cell 3 to the external plate 1. The adhesive layer 2 is made of a transparent material through which the solar rays may be transmitted.

The thin film type solar cell 3 is formed on the adhesive layer 2. Although not shown in detail, the thin film type solar cell 3 includes a front electrode, a semiconductor layer and a rear electrode.

The structure using the aforementioned thin film type solar cell according to the related art may be applied to a structure such as a window of a building or a sunroof of a car as described above. In this case, a user is located at the front of the thin film type solar cell 3.

Therefore, the user looks at the outside toward the external plate 1 at the front of the thin film type solar cell 3. At this time, the structure using the thin film type solar cell of the related art has a problem in that visibility is deteriorated by a light absorption wavelength range of the thin film type solar cell 3.

In more detail, the thin film type solar cell 3 includes a front electrode, a semiconductor layer, and a rear electrode, wherein the semiconductor layer is generally made of amorphous silicon (a-Si). However, the amorphous silicon (a-Si) is characterized in that it absorbs light of a short wavelength and transmits light of a long wavelength. Therefore, when the external solar rays transmit the thin film type solar cell 3, light of a long wavelength having a red color transmits the thin film type solar cell 3, whereby the external condition viewed by the user shows a red color.

In this respect, since the structure using the thin film type solar cell according to the related art is perceived by the user in a red color, visibility is deteriorated. Also, since the color of the structure cannot be changed, a problem occurs in that the structure cannot satisfy various demands of the user.

### SUMMARY OF THE INVENTION

Accordingly, the present invention is directed to a structure using a thin film type solar cell, which substantially obviates one or more problems due to limitations and disadvantages of the related art.

An advantage of the present invention is to provide a structure using a thin film type solar cell, of which visibility is improved and color may be changed.

Additional advantages and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a structure using a thin film type solar cell comprising an external plate exposed to solar rays; a first adhesive layer provided on an opposite surface of a surface of the external plate, which is exposed to the solar rays; a thin film type solar cell provided on the first adhesive layer; a second adhesive layer provided on the thin film type solar cell; and a protection layer provided on the second adhesive layer, wherein the second adhesive layer is made of a colored adhesive material.

The second adhesive layer is provided with colored pigments or dyes distributed to a transparent adhesive material.

Each of the external plate, the first adhesive layer and the protection layer may be made of a transparent material.

The thin film type solar cell may include a substrate; a plurality of first electrodes provided on the substrate and spaced apart from one another by interposing a first partition therebetween; a plurality of semiconductor layers provided on the first electrodes, provided with a contact portion therein, and spaced apart from one another by interposing a second partition therebetween; and a plurality of second electrodes provided on the plurality of semiconductor layers, connected to the first electrodes through the contact portion and spaced apart from one another by interposing the second partition therebetween.

The substrate is provided on an opposite surface of a surface of the first adhesive layer, which is in contact with the external plate, and in an area of the second partition, the solar rays pass through the external plate, the first adhesive layer, the substrate and the first electrode in due order, are changed to colored solar rays while passing through the second adhesive layer, and then pass through the protection layer.

The substrate is provided on an opposite surface of a surface of the second adhesive layer, which is in contact with the protection layer, and in an area of the second partition, the solar rays pass through the external plate, the first adhesive layer, the first electrode and the substrate in due order, are changed to colored solar rays while passing through the second adhesive layer, and then pass through the protection layer.

In another aspect of the present invention, there is provided a structure using a thin film type solar cell comprising an external plate exposed to solar rays; a first adhesive layer provided on an opposite surface of a surface of the external plate, which is exposed to the solar rays; a thin film type solar cell provided on the first adhesive layer; a second adhesive layer provided on the thin film type solar cell and made of a colored adhesive material; and a protection layer provided on the second adhesive layer, wherein the thin film type solar cell is provided with a plurality of holes through which the solar rays may pass.

The thin film type solar cell includes a substrate; a plurality of first electrodes provided on the substrate and spaced apart from one another by interposing a first partition therebetween; a plurality of semiconductor layers provided on the first electrodes, provided with a contact portion therein, and spaced apart from one another by interposing a second partition therebetween; and a plurality of second electrodes provided on the plurality of semiconductor layers, connected to the first electrodes through the contact portion and spaced apart from one another by interposing the second partition therebetween, and each of the plurality of holes is provided by removing the semiconductor layer and the second electrode.

The plurality of holes may be arranged between the first partition of one unit cell and the second partition of its neighboring unit cell.

The substrate is provided on an opposite surface of a surface of the first adhesive layer, which is in contact with the external plate, and in an area of the holes, the solar rays pass through the external plate, the first adhesive layer, the substrate and the first electrode in due order, are changed to colored solar rays while passing through the second adhesive layer, and then pass through the protection layer.

The substrate is provided on an opposite surface of a surface of the second adhesive layer, which is in contact with the protection layer, and in an area of the holes, the solar rays pass through the external plate, the first adhesive layer, the first electrode and the substrate in due order, are changed to colored solar rays while passing through the second adhesive layer, and then pass through the protection layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view illustrating a structure using a thin film type solar cell according to the related art;

FIG. 2 is a cross-sectional view illustrating a structure using a thin film type solar cell according to one embodiment of the present invention;

FIG. 3 is a cross-sectional view illustrating a structure using a thin film type solar cell according to another embodiment of the present invention;

FIG. 4 is a cross-sectional view illustrating a structure using a thin film type solar cell according to still another embodiment of the present invention;

FIG. 5 is a cross-sectional view illustrating a structure using a thin film type solar cell according to further still another embodiment of the present invention;

FIG. 6 is a cross-sectional view illustrating a structure using a thin film type solar cell according to further still another embodiment of the present invention;

FIG. 7 is a plane view illustrating a structure using a thin film type solar cell according to one embodiment of the present invention; and

FIG. 8 is a graph illustrating a change in light transmittance per wavelength according to the present invention.

### DETAILED DESCRIPTION OF THE INVENTION

Reference will now be made in detail to the exemplary embodiments of the present invention, examples of which are illustrated in the accompanying drawings. Wherever possible, the same reference numbers will be used throughout the drawings to refer to the same or like parts.

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

A shape, a size, a ratio, an angle, and a number disclosed in the drawings for describing embodiments of the present invention are merely an example, and thus, the present invention is not limited to the illustrated details. Like reference numerals refer to like elements throughout. In the following description, when the detailed description of the relevant known function or configuration is determined to unnecessarily obscure the important point of the present invention, the detailed description will be omitted. In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In description of embodiments of the present invention, when a structure (for example, an electrode, a line, a wiring, a layer, or a contact) is described as being formed at an upper portion/lower portion of another structure or on/under the other structure, this description should be construed as including a case where the structures contact each other and moreover, a case where a third structure is disposed therebetween.

In describing a time relationship, for example, when the temporal order is described as ‘after˜’, ‘subsequent˜’ ‘next˜’, and ‘before˜’, a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Features of various embodiments of the present invention may be partially or overall coupled to or combined with each other, and may be variously inter-operated with each other and driven technically as those skilled in the art can sufficiently understand. The embodiments of the present invention may be carried out independently from each other, or may be carried out together in co-dependent relationship.

Hereinafter, the preferred embodiment of the present invention will be described with reference to the accompanying drawing.

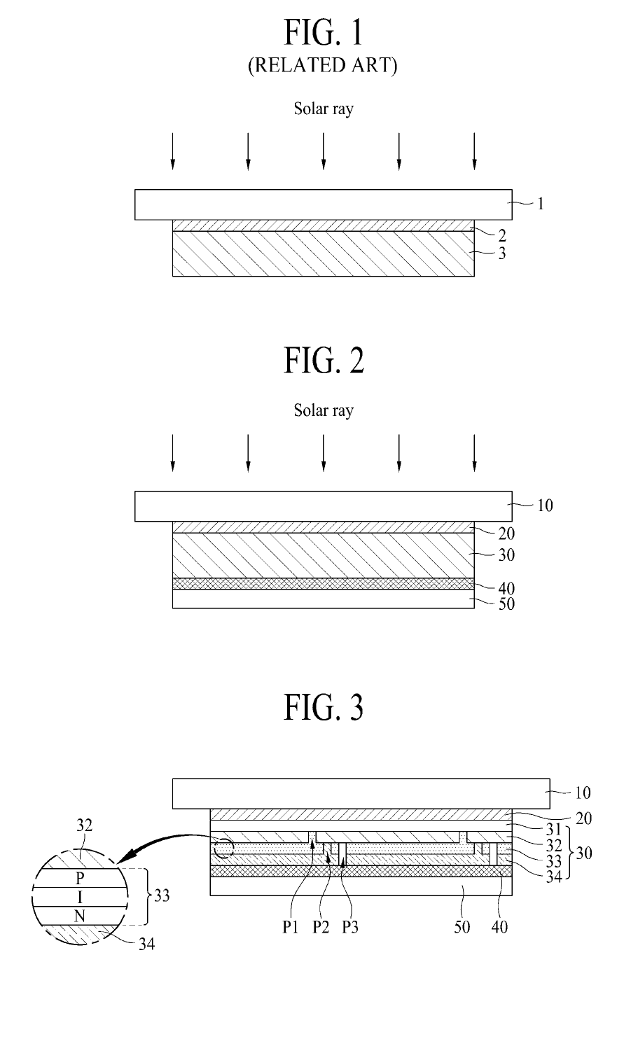

FIG. 2 is a cross-sectional view illustrating a structure using a thin film type solar cell according to one embodiment of the present invention.

As shown in FIG. 2, the structure using the thin film type solar cell according to one embodiment of the present invention includes an external plate 10, a first adhesive layer 20, a thin film type solar cell 30, a second adhesive layer 40, and a protection layer 50.

The external plate 10 is exposed to external solar rays and provided on an entire surface of the structure according to the present invention, and is made of a transparent material through which the solar rays may be transmitted.

The external plate 10 may be changed variously depending on purpose of uses to which the present invention is applied. For example, the external plate 10 may be made of a window of a building or a sunroof of a car.

The first adhesive layer 20 is formed on an inner surface of the external plate 10, which is not exposed to the solar rays. That is, the first adhesive layer 20 is formed on an opposite surface of the surface of the external plate 10, which is exposed to the solar rays.

The first adhesive layer 20 serves to bond the thin film type solar cell 30 to the inner surface of the external plate 10. The first adhesive layer 20 is made of a transparent adhesive material through which the solar rays may be transmitted.

For example, the first adhesive layer 20 may be made of a transparent adhesive such as polyvinyl butyral. The first adhesive layer 20 may be made of, but not limited to, an attachable film type. The first adhesive layer 20 may be made of a material obtained by hardening a liquid material.

The thin film type solar cell 30 is formed on the first adhesive layer 20. In more detail, the thin film type solar cell 30 is formed on an opposite surface of a surface of the first adhesive layer 20, which is in contact with the external plate 10.

Although not shown in detail, the thin film type solar cell 30 includes a front electrode, a semiconductor layer and a rear electrode. Various modifications known in the art may be made in the thin film type solar cell 30.

The second adhesive layer 40 is formed on the thin film type solar cell 30. In more detail, the second adhesive layer 40 is formed on an opposite surface of a surface of the thin film type solar cell 30, which is in contact with the first adhesive layer 20.

The second adhesive layer 40 serves to bond the protection layer 50 to the thin film type solar cell 30. Also, the second adhesive layer 40 serves to make various modifications in a color of the structure according to the present invention and improve visibility.

The aforementioned second adhesive layer 40 is comprised of a colored adhesive layer. In more detail, the second adhesive layer 40 may be made in such a manner that colored pigments or dyes are distributed into a transparent adhesive material. An example of the transparent adhesive material may include polyvinyl butyral. The second adhesive layer 40 may be made of an attachable film type or a material obtained by hardening a liquid material.

According to one embodiment of the present invention, since the second adhesive layer 40 is made of a colored adhesive material, the distributed pigments or dyes may be changed into various colors, whereby the structure having various colors may be obtained.

The protection layer 50 is formed on the second adhesive layer 40. In more detail, the protection layer 50 is formed on an opposite surface of a surface of the second adhesive layer 20, which is in contact with the thin film type solar cell 30.

The protection layer 50 serves to protect the thin film type solar cell 30, and may be made of a transparent material, for example, glass or transparent plastic, for visibility of a user.

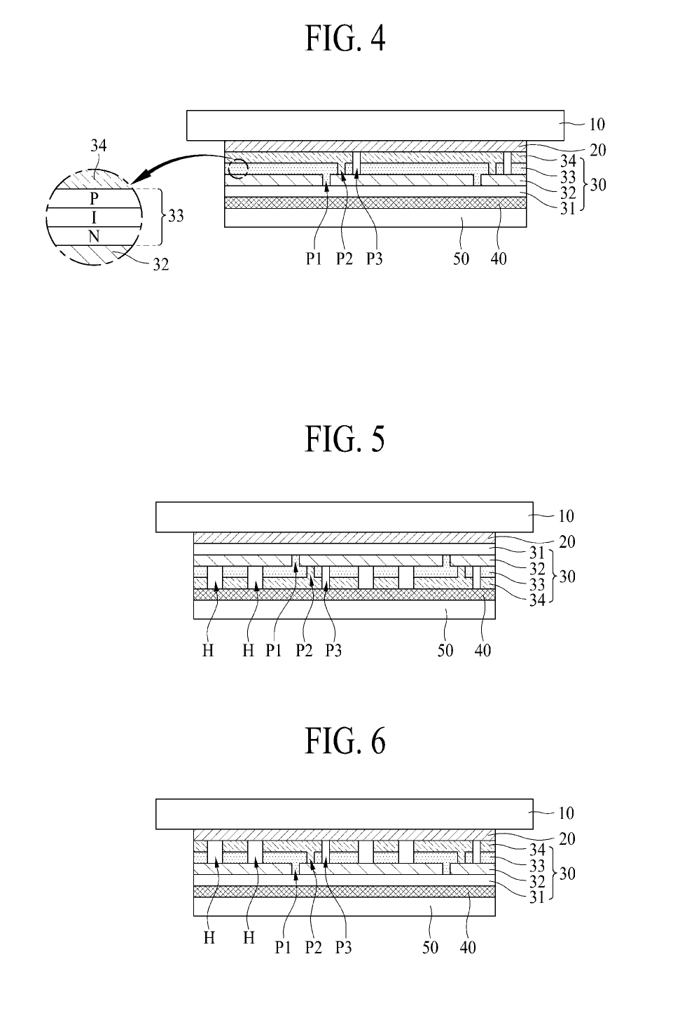

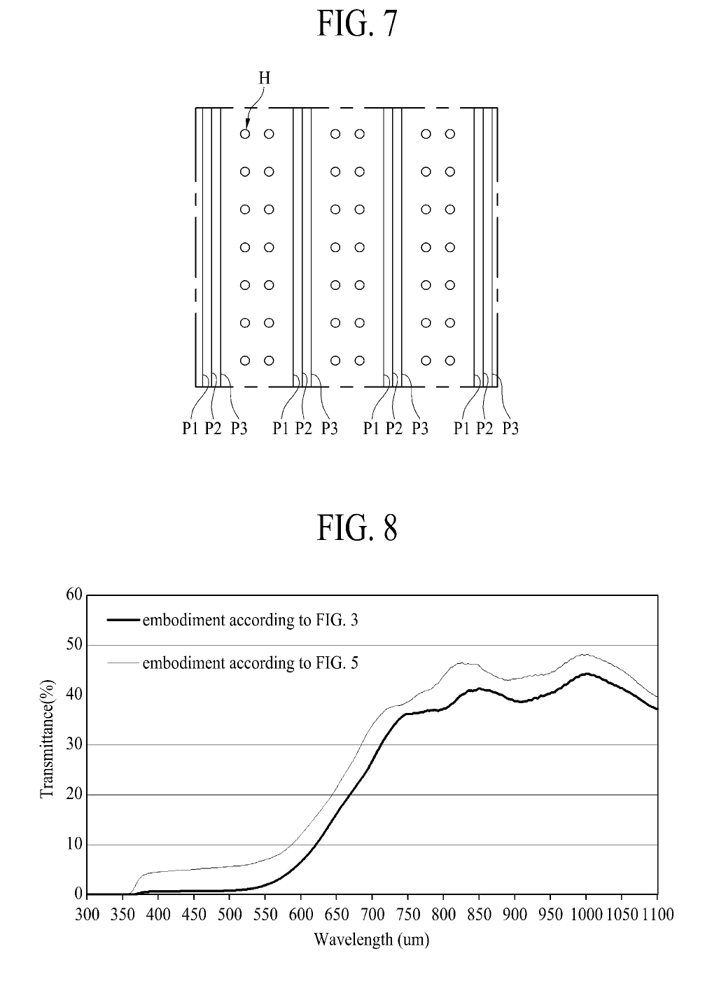

FIG. 3 is a cross-sectional view illustrating a structure using a thin film type solar cell according to another embodiment of the present invention. The structure of FIG. 3 is the same as that of FIG. 2 except that the thin film type solar cell 30 includes a plurality of unit cells connected to one another in series. Therefore, the same reference numbers are given to the same elements, and repeated description of the same elements will be omitted hereinafter.

As shown in FIG. 3, the structure using the thin film type solar cell according to another embodiment of the present invention includes an external plate 10, a first adhesive layer 20, a thin film type solar cell 30, a second adhesive layer 40, and a protection layer 50.

Since the external plate 10, the first adhesive layer 20, the second adhesive layer 40 and the protection layer 50 are the same as those of the aforementioned description, their repeated description will be omitted.

The thin film type solar cell 30 includes a substrate 31, a first electrode 32, a semiconductor layer 33, and a second electrode 34.

The substrate 31 is formed on the first adhesive layer 20. In more detail, the substrate 31 is formed on an opposite surface of a surface of the first adhesive layer 20, which is in contact with the external plate 10. The substrate 31 may be made of a transparent glass or transparent plastic.

The first electrode 32 is formed on the substrate 31. In more detail, the first electrode 32 is formed on an opposite surface of a surface of the substrate 31, which is in contact with the first adhesive layer 20.

The first electrode 32 may be made of a transparent conductive oxide such as ZnO, ZnO:B, ZnO:Al, SnO₂, SnO₂:F or ITO (Indium Tin Oxide). The first electrode 32 is formed per unit cell, and thus each of a plurality of first electrodes 32 is spaced apart from another one by interposing a first partition P1 therebetween.

The semiconductor layer 33 is formed on the first electrode 32. In more detail, the semiconductor layer 33 is formed on an opposite surface of a surface of the first electrode 32, which is in contact with the substrate 31. Also, the semiconductor layer 33 is formed in the first partition P1. Therefore, the semiconductor layer 33 is in contact with the substrate 31 through the first partition P1.

The semiconductor layer 33 is formed per unit cell, and thus each of a plurality of semiconductor layers 33 is spaced apart from another one by interposing a second partition P3 therebetween. Also, since each semiconductor layer 33 is provided with a contact portion P2, electric connection between the first electrode 32 and the second electrode 34 may be made through the contact portion P2, whereby the unit cells may be connected to one another in series.

As will be aware of it from an enlarged view enlarged by an arrow, the semiconductor layer 33 may be formed in a PIN structure that includes a P type semiconductor layer, an I type semiconductor layer, and an N type semiconductor layer. In this way, if the semiconductor layer 33 is formed in a PIN structure, the I type semiconductor layer is depleted by the P type semiconductor layer and the N type semiconductor layer, whereby an electric field is generated therein. Also, holes and electrons generated by solar rays are drifted by the electric field, whereby the holes may be collected in the first electrode 32 through the P type semiconductor layer and the electrons may be collected in the second electrode 34 through the N type semiconductor layer.

At this time, the P type semiconductor layer may be disposed to be close to the first electrode 32, the N type semiconductor layer may be disposed to be close to the second electrode 34, and the I type semiconductor layer may be disposed between the P type semiconductor layer and the N type semiconductor layer.

In other words, the P type semiconductor layer may be formed to be close to an incident surface of the solar rays, and the N type semiconductor layer may be formed to be far away from the incident surface of the solar rays. Generally, since drift mobility of the holes is lower than that of the electrons, the P type semiconductor layer is formed to be close to the incident surface of the solar rays to maximize collection efficiency based on the incident light.

The P type semiconductor layer may be made by, but not limited to, doping a P type dopant on amorphous silicon, the I type semiconductor layer may be made of, but not limited to, amorphous silicon, and the N type semiconductor layer may be made by, but not limited to, doping an N type dopant on amorphous silicon.

The second electrode 34 is formed on the semiconductor layer 33. In more detail, the second electrode 34 is formed on an opposite surface of a surface of the semiconductor layer 33, which is in contact with the first electrode 32.

The second electrode 34 may be made of a transparent conductive oxide such as ZnO, ZnO:B, ZnO:Al, SnO₂, SnO₂:F or ITO (Indium Tin Oxide), or may be made of metal such as Ag, Al, Ag+Mo, Ag+Ni, or Ag+Cu. The second electrode 34 is formed per unit cell, and thus each of a plurality of second electrodes 34 is spaced apart from another one by interposing a second partition P3 therebetween. Also, each second electrode 34 is connected to each first electrode 32 through the contact portion P2.

Meanwhile, although not shown, a transparent conductive oxide layer such as ZnO, ZnO:B, ZnO:Al, SnO₂, SnO₂:F or ITO (Indium Tin Oxide) may additionally be formed between the semiconductor layer 33 and the second electrode 34.

According to another embodiment of the present invention, the thin film type solar cell 30 includes a plurality of unit cells connected to one another in series. Therefore, the first partition P1, the contact portion P2, and the second partition P3 are provided as described above. At this time, the semiconductor layer 33 is not formed in the contact portion P2 and the second partition P3.

Therefore, the contact portion P2 and the second partition P3 are less affected by the semiconductor layer 33, whereby a problem that an external condition be shown in a red color may not occur. Particularly, the second electrode 34 is not formed in an area of the second partition P3. Therefore, in the area of the second partition P3, the solar rays pass through the transparent external plate 10, the first adhesive layer 20, the substrate 31 and the first electrode 32 in due order and then are changed to colored solar rays while passing through the colored second adhesive layer 40. Afterwards, the solar rays may be incident upon the eyes of the user by passing through the transparent protection layer 50. Therefore, in the area of the second partition P3, the color desired to be realized by the second adhesive layer 40 may be obtained more exactly.

FIG. 4 is a cross-sectional view illustrating a structure using a thin film type solar cell according to still another embodiment of the present invention. The structure of FIG. 4 is the same as that of FIG. 3 except that arrangement of the thin film type solar cell 30 in which a plurality of unit cells are connected to one another in series is changed. Therefore, the same reference numbers are given to the same elements, and repeated description of the same elements will be omitted hereinafter.

As shown in FIG. 4, according to still another embodiment of the present invention, a thin film type solar cell 30 comprised of a substrate 31, a first electrode 32, a semiconductor layer 33, and a second electrode 34 is formed between a first adhesive layer 20 and a second adhesive layer 40.

In this case, a deposition order of the substrate 31, the first electrode 32, the semiconductor layer 33 and the second electrode 34 is different from that of FIG. 3.

In more detail, the substrate 31 is formed on the second adhesive layer 40. In more detail, the substrate 31 is formed on an opposite surface of a surface of the second adhesive layer 40, which is in contact with the protection layer 50.

The first electrode 32 is formed on the substrate 31. In more detail, the first electrode 32 is formed on an opposite surface of a surface of the substrate 31, which is in contact with the second adhesive layer 40. In the same manner as the aforementioned description, each of the plurality of first electrodes 32 is spaced apart from another one by interposing the first partition P1 therebetween.

The semiconductor layer 33 is formed on the first electrode 32. In more detail, the semiconductor layer 33 is formed on an opposite surface of a surface of the first electrode 32, which is in contact with the substrate 31.

In the same manner as the aforementioned description, the semiconductor layer 33 is formed within the first partition P1, so that the semiconductor layer 33 is in contact with the substrate 31. Also, each of a plurality of semiconductor layers 33 is spaced apart from another one by interposing the second partition P3 therebetween. Also, since each semiconductor layer 33 is provided with a contact portion P2, electric connection between the first electrode 32 and the second electrode 34 may be made through the contact portion P2.

As will be aware of it from an enlarged view enlarged by an arrow, the semiconductor layer 33 may be formed in a PIN structure that includes a P type semiconductor layer, an I type semiconductor layer, and an N type semiconductor layer. At this time, the P type semiconductor layer may be disposed to be close to the second electrode 34, the N type semiconductor layer may be disposed to be close to the first electrode 32, and the I type semiconductor layer may be disposed between the P type semiconductor layer and the N type semiconductor layer. In other words, the P type semiconductor layer may be formed to be close to an incident surface of the solar rays, and the N type semiconductor layer may be formed to be far away from the incident surface of the solar rays.

The second electrode 34 is formed on the semiconductor layer 33. In more detail, the second electrode 34 is formed on an opposite surface of a surface of the semiconductor layer 33, which is in contact with the first electrode 32. Each of a plurality of second electrodes 34 is spaced apart from another one by interposing the second partition P3 therebetween. Also, each second electrode 34 is connected to each first electrode 32 through the contact portion P2.

The second electrode 34 is formed on the first adhesive layer 20 in contact with the first adhesive layer 20. In more detail, the second electrode 34 is formed on an opposite surface of a surface of the first adhesive layer 20, which is in contact with the external plate 10.

According to another embodiment of the present invention described as above, since the semiconductor layer 33 is not formed in the contact portion P2 and the second partition P3, the contact portion P2 and the second partition P3 are less affected by the semiconductor layer 33, whereby a problem that an external condition is shown in a red color may not occur.

Particularly, the second electrode 34 is not formed in an area of the second partition P3. Therefore, in the area of the second partition P3, the solar rays pass through the transparent external plate 10, the first adhesive layer 20, the first electrode 32 and the substrate 31 in due order and then are changed to colored solar rays while passing through the colored second adhesive layer 40. Afterwards, the solar rays may be incident upon the eyes of the user by passing through the transparent protection layer 50. Therefore, in the area of the second partition P3, the color desired to be realized by the second adhesive layer 40 may be obtained more exactly.

FIG. 5 is a cross-sectional view illustrating a structure using a thin film type solar cell according to further still another embodiment of the present invention. The structure of FIG. 5 is the same as that of FIG. 3 except that the structure of FIG. 5 additionally includes a plurality of holes H. Therefore, the same reference numbers are given to the same elements, and repeated description of the same elements will be omitted hereinafter.

As shown in FIG. 5, according to further still another embodiment of the present invention, holes H are provided for a plurality of unit cells.

The holes H are formed by removing the semiconductor layer 33 and the second electrode 34. Therefore, the semiconductor layer 33 and the second electrode 34 are not formed in the area of the holes H in the same manner as the area of the second partition P3.

As a result, in the area of the holes H like the area of the second partition P3, the solar rays pass through the transparent external plate 10, the first adhesive layer 20, the substrate 31 and the first electrode 32 in due order and then are changed to colored solar rays while passing through the colored second adhesive layer 40. Afterwards, the solar rays may be incident upon the eyes of the user by passing through the transparent protection layer 50. Therefore, in the areas of the second partition P3 and the holes H, the color desired to be realized by the second adhesive layer 40 may be obtained more exactly.

Particularly, the embodiment according to FIG. 5 has an advantage in that the colored solar rays more improved than the embodiment of FIG. 3 as much as the area of the holes H may be realized.

The plurality of holes H may be formed between the first partition P1 of one unit cell and the second partition P3 of a neighboring unit cell as shown in FIG. 5. Although the first partition P1 and the second partition P3 may be formed in a shape of a line to partition the unit cells from each another, each of the plurality of holes H is formed in a shape of an island not a line. Accordingly, each of the plurality of holes H does not partition the unit cells from each another, whereby the area between the respective holes H act as a useful cell. The shape of the hole H will be understood more easily referring to FIG. 7 which will be described later.

FIG. 6 is a cross-sectional view illustrating a structure using a thin film type solar cell according to further still another embodiment of the present invention. The structure of FIG. 6 is the same as that of FIG. 4 except that the structure of FIG. 6 additionally includes a plurality of holes H. Therefore, the same reference numbers are given to the same elements, and repeated description of the same elements will be omitted hereinafter.

As shown in FIG. 6, according to further still another embodiment of the present invention, holes H are provided for a plurality of unit cells.

The holes H are formed by removing the semiconductor layer 33 and the second electrode 34. Therefore, the semiconductor layer 33 and the second electrode 34 are not formed in the area of the holes H in the same manner as the area of the second partition P3.

As a result, in the area of the holes H like the area of the second partition P3, the solar rays pass through the transparent external plate 10, the first adhesive layer 20, the first electrode 32 and the substrate 31 in due order and then are changed to colored solar rays while passing through the colored second adhesive layer 40. Afterwards, the solar rays may be incident upon the eyes of the user by passing through the transparent protection layer 50. Therefore, in the areas of the second partition P3 and the holes H, the color desired to be realized by the second adhesive layer 40 may be obtained more exactly.

Particularly, the embodiment according to FIG. 6 has an advantage in that the colored solar rays more improved than the embodiment of FIG. 4 as much as the area of the holes H may be realized.

In the same manner as the embodiment according to FIG. 5, the plurality of holes H may be formed between the first partition P1 of one unit cell and the second partition P3 of a neighboring unit cell, and each of the plurality of holes H is formed in a shape of an island not a line.

FIG. 7 is a plane view illustrating a structure using a thin film type solar cell according to one embodiment of the present invention, and corresponds to a plane view of the structures according to FIGS. 5 and 6 above.

As shown in FIG. 7, as the first partition P1, the contact portion P2 and the second partition P3 are repeated, a plurality of unit cells are connected to one another in series. An area from any one of first partitions P1 to its neighboring another first partition P1 may be defined as one unit cell, or an area from any one of second partitions P3 to its neighboring another second partition P3 may be defined as one unit cell.

A plurality of holes H are provided for each of the plurality of unit cells. Each of the plurality of holes H is formed in a shape of an island on the plane view as shown. For example, although each of the plurality of holes H may be formed in a shape of a circle, various modifications such as a oval shape and a polygonal shape may be made in the shape of each of the plurality of hole H without limitation to the circle shape.

As described above, the plurality of holes H may be formed between the first partition P1 of one unit cell and the second partition P3 of its neighboring cell. The first partition P1 and the second partition P3 are formed in a shape of a line, and each of the plurality of holes H is formed in a shape of an island.

The aforementioned holes H may be arranged, but not limited to, in parallel with the line shape of the first partition P1, the contact portion P2 and the second partition P3 as shown.

Also, the plurality of holes H may be arranged in a plurality of rows parallel with the line shape of the first partition P1, the contact portion P2 and the second partition P3. As shown, although the plurality of holes H may be arranged in two rows, the holes H may be arranged in three rows or more.

If the number of holes H is increased or an area of the hole H is increased, coloring may be improved but efficiency of the solar cell is deteriorated as much as the improved coloring. Therefore, it is preferable that the number of holes H and the area of the hole H are appropriately controlled considering coloring and efficiency of the solar cell.

FIG. 8 is a graph illustrating a change in light transmittance per wavelength (300 nm to 1100 nm) according to the present invention.

As shown in FIG. 8, it is noted that light transmittance is more excellent in a long wavelength than in a short wavelength. Therefore, it is noted that the structure according to the present invention is seen in a red color as a whole. However, it is noted that light transmittance at an overall wavelength in the embodiment of FIG. 5 is more excellent than that in the embodiment of FIG. 3. Particularly, in case of a long wavelength near 700 nm approximately, it is noted that the embodiment of FIG. 3 shows light transmittance of about 23%, whereas the embodiment of FIG. 5 shows light transmittance of about 28%. As a result, the structure according to the present invention is seen as a relatively light red color in the embodiment of FIG. 5 as compared with the embodiment of FIG. 3, whereby visibility may be improved in the embodiment of FIG. 5.

The following Table 1 shows results of internal intensity of light measured in the embodiment of FIG. 3 and the embodiment of FIG. 5. As shown in Table 1, the embodiment of FIG. 3 shows intensity of light of 325 W/m², whereas the embodiment of FIG. 5 shows intensity of light of 373 W/m², whereby it is noted that relatively high internal intensity of light may be obtained in the embodiment of FIG. 5 as compared with the embodiment of FIG. 3.

TABLE 1

| | Embodiment of FIG. 3 | Embodiment of FIG. 5 |
|---|---|---|
| Internal intensity of light | 325 W/m² | 373 W/m² |

Therefore, if the embodiment of FIG. 5 is applied to a greenhouse, intensity of light inside the greenhouse may be increased by increase of transmittance during a process of a dot cell such as the hole H, and intensity of light may be increased in proportional to an area of the hole. For example, if the area of the hole H is formed in the range of 10%, intensity of light may be increased as much as 10%. As a result, a growth of living things may be improved through increase of intensity of light inside the greenhouse.

According to the present invention described as above, the following advantages may be obtained.

According to one embodiment of the present invention, since the second adhesive layer is made of a colored adhesive material, distributed pigments or dyes may be changed to various colors, whereby the structure having various colors may be obtained. As a result, according to one embodiment of the present invention, the structure having various colors in addition to a red color may be obtained, and visibility may be improved.

In addition, the structure according to another embodiment of the present invention may be applied to a greenhouse. In this case, intensity of light inside the greenhouse may be increased by increase of transmittance through the hole H, and intensity of light may be increased in proportional to an area of the hole, whereby a growth of living things may be improved.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A structure using a thin film type solar cell comprising:
an external plate exposed to solar rays;
a first adhesive layer provided on an opposite surface of a surface of the external plate, which is exposed to the solar rays;
a thin film type solar cell provided on the first adhesive layer;
a second adhesive layer provided on the thin film type solar cell; and
a protection layer provided on the second adhesive layer,
wherein the second adhesive layer is made of a colored adhesive material.

2. The structure using a thin film type solar cell of claim 1, wherein the second adhesive layer is provided with colored pigments or dyes distributed to a transparent adhesive material.

3. The structure using a thin film type solar cell of claim 1, wherein each of the external plate, the first adhesive layer and the protection layer is made of a transparent material.

4. The structure using a thin film type solar cell of claim 1, wherein the thin film type solar cell includes:
a substrate;
a plurality of first electrodes provided on the substrate and spaced apart from one another by interposing a first partition therebetween;
a plurality of semiconductor layers provided on the first electrodes, provided with a contact portion therein, and spaced apart from one another by interposing a second partition therebetween; and
a plurality of second electrodes provided on the plurality of semiconductor layers, connected to the first electrodes through the contact portion and spaced apart from one another by interposing the second partition therebetween.

5. The structure using a thin film type solar cell of claim 4, wherein the substrate is provided on an opposite surface of a surface of the first adhesive layer, which is in contact with the external plate, and
wherein in an area of the second partition, the solar rays pass through the external plate, the first adhesive layer, the substrate and the first electrode in due order, are changed to colored solar rays while passing through the second adhesive layer, and then pass through the protection layer.

6. The structure using a thin film type solar cell of claim 4, wherein the substrate is provided on an opposite surface of a surface of the second adhesive layer, which is in contact with the protection layer, and
wherein in an area of the second partition, the solar rays pass through the external plate, the first adhesive layer, the first electrode and the substrate in due order, are changed to colored solar rays while passing through the second adhesive layer, and then pass through the protection layer.

7. A structure using a thin film type solar cell comprising:
an external plate exposed to solar rays;
a first adhesive layer provided on an opposite surface of a surface of the external plate, which is exposed to the solar rays;
a thin film type solar cell provided on the first adhesive layer;
a second adhesive layer provided on the thin film type solar cell and made of a colored adhesive material; and
a protection layer provided on the second adhesive layer,
wherein the thin film type solar cell is provided with a plurality of holes through which the solar rays may pass.

8. The structure using a thin film type solar cell of claim 7, wherein the thin film type solar cell includes:
a substrate;
a plurality of first electrodes provided on the substrate and spaced apart from one another by interposing a first partition therebetween;
a plurality of semiconductor layers provided on the first electrodes, provided with a contact portion therein, and spaced apart from one another by interposing a second partition therebetween; and
a plurality of second electrodes provided on the plurality of semiconductor layers, connected to the first electrodes through the contact portion and spaced apart from one another by interposing the second partition therebetween, and
each of the plurality of holes is provided by removing the semiconductor layer and the second electrode.

9. The structure using a thin film type solar cell of claim 8, wherein the plurality of holes are arranged between the first partition of one unit cell and the second partition of its neighboring unit cell.

10. The structure using a thin film type solar cell of claim 8, wherein the substrate is provided on an opposite surface of a surface of the first adhesive layer, which is in contact with the external plate, and
wherein in an area of the holes, the solar rays pass through the external plate, the first adhesive layer, the substrate and the first electrode in due order, are changed to colored solar rays while passing through the second adhesive layer, and then pass through the protection layer.

11. The structure using a thin film type solar cell of claim 8, wherein the substrate is provided on an opposite surface of a surface of the second adhesive layer, which is in contact with the protection layer, and
wherein in an area of the holes, the solar rays pass through the external plate, the first adhesive layer, the first electrode and the substrate in due order, are changed to colored solar rays while passing through the second adhesive layer, and then pass through the protection layer.
